(19) United States
(12) Patent Application Publication
(10) Pub. No.: US 2023/0041622 A1
(43) Pub. Date: Feb. 9, 2023

(54) INTEGRATED CHIP, FERROELECTRIC MEMORY DEVICE AND MANUFACTURING METHOD THEREOF

(71) Applicant: Taiwan Semiconductor Manufacturing Company, Ltd., (US)

(72) Inventors: Oreste Madia, Hsinchu (TW); Georgios Vellianitis, Heverlee (BE); Gerben Doornbos, Kessel-Lo (BE); Marcus Johannes Henricus Van Dal, Linden (BE)

(73) Assignee: Taiwan Semiconductor Manufacturing Company, Ltd., Hsinchu (TW)

(21) Appl. No.: 17/669,378

(22) Filed: Feb. 11, 2022

Related U.S. Application Data
(60) Provisional application No. 63/230,044, filed on Aug. 5, 2021.

(51) Int. Cl. H01L 27/1159; H01L 29/66; H01L 29/78

(52) U.S. Cl. CPC H01L 27/1159; H01L 29/6684; H01L 29/78391

(57) ABSTRACT

A ferroelectric memory device includes a substrate, a gate electrode, a ferroelectric layer, and a pair of source/drain electrodes. The gate electrode is disposed over the substrate. The ferroelectric layer at least covers two adjacent side surfaces of the gate electrode. The pair of source/drain electrodes is over the substrate and disposed on two opposite sides of the gate electrode respectively.

### CROSS-REFERENCE TO RELATED APPLICATION

This application claims the priority benefit of U.S. provisional applications Ser. No. 63/230,044, filed on Aug. 5, 2021. The entirety of the above-mentioned patent application is hereby incorporated by reference herein and made a part of this specification.

### BACKGROUND

Many modern day electronic devices include non-volatile memory. Non-volatile memory is electronic memory that is able to store data in the absence of power. A promising candidate for the next generation of non-volatile memory is ferroelectric field effect transistor (FeFET) in some instances. FeFET has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 7 illustrate partial cross sectional views of intermediate stages in the manufacturing of a ferroelectric memory device according to some embodiments of the present disclosure.

FIG. 8 to FIG. 13 illustrate partial cross sectional views of intermediate stages in the manufacturing of a ferroelectric memory device according to some embodiments of the present disclosure.

FIG. 14 to FIG. 17 illustrate partial cross sectional views of intermediate stages in the manufacturing of a ferroelectric memory device according to some embodiments of the present disclosure.

FIG. 18 to FIG. 20 illustrate partial cross sectional views of intermediate stages in the manufacturing of a ferroelectric memory device according to some embodiments of the present disclosure.

FIG. 21 to FIG. 26 illustrate partial cross sectional views of intermediate stages in the manufacturing of a ferroelectric memory device according to some embodiments of the present disclosure.

FIG. 27 to FIG. 32 illustrate partial cross sectional views of intermediate stages in the manufacturing of a ferroelectric memory device according to some embodiments of the present disclosure.

FIG. 33 to FIG. 37 illustrate partial cross sectional views of intermediate stages in the manufacturing of a ferroelectric memory device according to some embodiments of the present disclosure.

FIG. 38 illustrates a cross-sectional view of some embodiments of an integrated chip comprising a logic device and a ferroelectric memory device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip, a ferroelectric memory device and the method of forming the ferroelectric memory device are provided in accordance with various embodiments. Like reference numbers and characters in the figures below refer to like components. Although method embodiments may be discussed as being performed in a particular order, other method embodiments may be performed in any logical order. In general terms, embodiments of the present disclosure may provide for an improved approach to significantly reduce a wake-up phase of a ferroelectric memory, while not causing any losses in terms for overall polarization and capacitance, so as to decrease power consumption of the ferroelectric memory cell, and increase endurance and discrete data states of the ferroelectric memory cell.

In detail, some ferroelectric memory (e.g., ferroelectric random-access memory (FeRAM)) comprise a ferroelectric memory cell. The ferroelectric memory cell comprises a ferroelectric structure (e.g., a single layer or composite layers) disposed between a first electrode and a second electrode. In other embodiments, ferroelectric structure may be integrated in a back-end-of-line (BEOL) structure between metal lines or be integrated in a gate structure between a gate electrode and a semiconductor substrate. (e.g., ferroelectric field-effect transistor (FeFET)). The ferroelectric structure is configured to switch between polarization states to store data (e.g., binary “0” and “1”). The ferroelectric memory is often disposed on an integrated chip (IC) comprising other types of semiconductor devices (e.g., metal-oxide semiconductor field-effect transistors (MOSFETs), bipolar junction transistors (BJTs), high-electron-mobility transistors (HEMTs), etc.).

In some embodiments, the ferroelectric layer includes a plurality of crystalline domains (i.e., ferroelectric domains) distributed throughout the ferroelectric material of the ferroelectric layer. While applying the positive or negative voltage pulses, a polarization of each individual ferroelectric domain will rotate to align itself in a same direction that corresponds to the direction of the voltage pulse. For example, while applying the positive voltage pulse, each ferroelectric domain may be set to a negative polarization state, and, while applying the negative voltage pulse, each ferroelectric domain may be set to a positive polarization state, or vice versa. As the plurality of ferroelectric domains are set to a same polarization state, the ferroelectric layer will have a polarization state that corresponds to the plurality of ferroelectric domains.

A challenge with the above ferroelectric layer is a variation in grain sizes and/or a variation in size of the ferroelectric domains across the ferroelectric material. The size of the ferroelectric domains may affect a voltage required to set the polarization of each ferroelectric domain. Further, the ferroelectric domain size correlates to a corresponding grain size, such that the grain size may affect the voltage required to set the polarization of each ferroelectric domain. Thus, an absolute value of a voltage applied to the first electrode may be increased to ensure each ferroelectric domain in the ferroelectric material switches polarization, and/or a duration of an applied voltage pulse may be increased to facilitate complete switching of each ferroelectric domain. This may increase a power consumption of the ferroelectric memory cell, reduce endurance of the ferroelectric memory cell, and/or reduce discrete data states of the ferroelectric memory cell.

Furthermore, tuning of grain sizes and/or ferroelectric domain sizes may include changing interfacial materials in contact with the ferroelectric layer, adjusting a doping type and/or concentration of the ferroelectric material, and/or adjusting an annealing process (e.g., changing the time and temperature of the annealing process) performed on the ferroelectric layer. However, the aforementioned tuning processes is rather complicated and may not accurately decrease and/or restrict the ferroelectric domain size.

Accordingly, various embodiments of the present disclosure relate to a ferroelectric memory cell having a ferroelectric layer with ferroelectric domains that are relatively small. In some embodiments, the ferroelectric memory device includes a gate electrode disposed over a semiconductor substrate, and a ferroelectric layer conformally covering the gate electrode. The ferroelectric layer at least covers two adjacent side surfaces of the gate electrode. In other words, such that the ferroelectric layer extends along a protruding edge of the gate electrode, which intrinsically creates a plurality of crystalline domains without adjusting any doping type, concentration of the ferroelectric material, and/or adjusting an annealing process (e.g., changing the time and temperature of the annealing process) performed on the ferroelectric layer. The arrangement is configured to reduce the size of the ferroelectric domains in the ferroelectric layer, thereby decreasing power consumption of the ferroelectric memory cell, and increasing endurance and discrete data states of the ferroelectric memory cell.

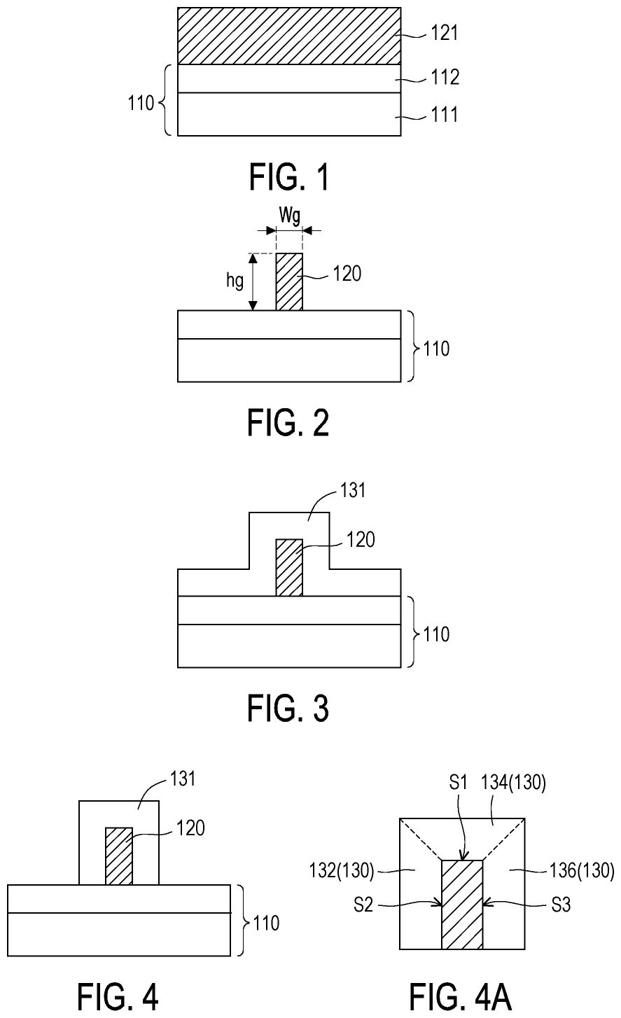

FIG. 1 to FIG. 7 illustrate partial cross sectional views of intermediate stages in the manufacturing of a ferroelectric memory device according to some embodiments of the present disclosure. It is understood that additional operations can be provided before, during, and after the processes shown by FIG. 1 to FIG. 7, and some of the operations described below can be replaced or eliminated, for additional embodiments of the method. The order of the operations/processes may be interchangeable. Material, configuration, dimensions and/or processes the same as or similar to the foregoing embodiments described with FIG. 1 to FIG. 7 may be employed in the following embodiments, and detailed explanation thereof may be omitted.

Referring to FIG. 1, in accordance with some embodiments of the disclosure, a substrate 110 is provided. In some embodiments, the substrate 110 may include any type of semiconductor body (e.g., monocrystalline silicon/CMOS bulk, silicon-germanium (SiGe), silicon on insulator (SOI), etc.). The substrate 110 can be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide (GaAs), indium gallium arsenide (InGaAs), indium arsenide (InAs), indium phosphide (InP), indium antimonide (InSb), gallium arsenic phosphide (GaAsP), or gallium indium phosphide (GaInP)), or the like. Further, the substrate 110 may include an epitaxial layer (epi-layer), which may be strained for performance enhancement, and/or may include a silicon-on-insulator (SOI) structure. In some embodiment, the substrate 110 may be a silicon-on-insulator substrate or another substrate with a dielectric layer on an upper surface. For example, the substrate 110 may be a wafer in a BEOL process, which includes an inter-layer dielectric layer on the top surface of the substrate 110. In the description herein, it is assumed, for descriptive purposes, that the substrate 110 includes a dielectric layer 112 over a silicon base layer 111, and the dielectric layer 112 may include silicon oxide or any suitable low-k dielectric material.

With now reference to FIG. 1 and FIG. 2, then, a metal layer 121 is formed over the substrate 110 through, for example, a physical vapor deposition process such as a sputtering process, or other suitable deposition processes. In some embodiments, the metal layer 121 may be globally deposited and later patterned (e.g., wet etching and/or dry etching) to define the shape of a gate electrode 120 of a ferroelectric memory device (e.g., the ferroelectric memory device 100 shown in FIG. 7). For example, a process for forming the gate electrode 120 over the substrate 110 may include forming a masking layer over/on the metal layer 121 and patterning the metal layer 121 according to the masking layer by an etch (e.g., wet/wet etching and/or dry etching). The etch removes unmasked portions of the metal layer 121, thereby forming the gate electrode 120. Subsequently, the masking layer may be stripped away. Alternatively or additionally, the gate electrode 120 may be directly formed with a desired shape through, for example, a lift-off process. Other approaches to form and shape the gate electrode 120 are also possible and included in the disclosure. The material of the gate electrode 120 may include poly Si, Al, Ru, Mo, Ta, Ti, Nb, Cu, W, Ni, Pd, P1, Au, or binary materials such as AlN, NiAl, TiAl, TiAlN, TiC, and other suitable materials. In the present embodiments, the gate electrode 120 is formed in an upright manner, which means a height (i.e., thickness) h_{g} of the gate electrode 120 is substantially greater than a width w_{g} of the gate electrode 120. However, the disclosure is not limited thereto. In other embodiment, the gate electrode may be formed in layer form, which means a thickness of the gate electrode is substantially smaller than a width of the gate electrode. Alternatively, the gate electrode may be any other suitable shapes.

In some embodiments, a pair of (doped) source/drain regions may be formed in the substrate 110. The pair of source/drain regions are formed on two opposite sides of the gate electrode 120. In one embodiment, the source/drain regions are aligned on the edges of the gate electrode 120. In some embodiments, the pair of source/drain regions are formed by an ion implantation process and may utilize a masking layer (not shown) to selectively implant ions in the substrate 110. In further embodiments, the gate electrode 120 may be utilized as the masking layer to form the pair of source/drain regions. Alternatively, or in addition, an epitaxial growth process may be used to form and/or expand the doped source/drain regions. An annealing process may be carried out for the doped source/drain regions. It is noted that the doped source/drain regions and other detail features of the substrate 110 may be omitted in the figures for purposes of clarity and simplicity.

With now reference to FIG. 3 and FIG. 4, a ferroelectric layer 130 is formed over the gate electrode 120. In some embodiment, an initial ferroelectric layer 131 may be globally deposited and conformally cover the gate electrode 120 and a top surface of the substrate 110, and later patterned (e.g., wet etching and/or dry etching) to form individual ferroelectric layers 130 that conformally covers the gate electrodes 120 respectively. In some embodiments, a thickness of the ferroelectric layer 130 may be controlled or tuned based on the device design or circuit design of the ferroelectric memory device. In some embodiments, the thickness of ferroelectric layer 130 is in the range from 1 nm to 15 nm. The material of ferroelectric layer 131 may or may not be ferroelectric prior to annealing. If it is not, it will become ferroelectric during subsequent processing. The ferroelectric layer 130 includes electric dipoles. Examples of ferroelectric materials include hafnium oxide (HfO₂), hafnium silicon oxide (HfSiO), hafnium zirconium oxide (HfZrO), aluminum oxide (Al₂O₃), titanium oxide (TiO₂), lanthanum oxide (LaOₓ), BaSrTiOₓ (BST), PbZrTiOₓ (PZT), or the like. Some of these materials (such as HfO₂, HfSiOₓ, HfZrOₓ, Al₂O₃, TiO₂, and LaOₓ) include the same elements as some high-k dielectric materials but may differ in the ratios of elements or in crystal structure. The ferroelectric material may be formed using CVD, PVD, ALD or the like. In some embodiments, the ferroelectric material such as HfO₂, HZO, etc., may be doped with dopants such as La, Sc, Gd, Y, Al, and C, Ge, Ni, Mo, B, etc.

In some embodiments, an annealing step may also be carried out for forming the ferroelectric layers 130. The annealing process may be performed using thermal annealing, microwave annealing, laser annealing, or other applicable methods. The annealing temperature may in the range from 200° C. to 600° C. This annealing may be lower in temperature or shorter in duration than the annealing used on source/drain regions, which is typically at least 5 second at 1000° C. However, the disclosure is not limited thereto.

With now reference to FIG. 4 and FIG. 4A, in some embodiments, the ferroelectric layer 130 at least covers two adjacent side surfaces of the gate electrode 120. In an embodiment, the ferroelectric layer 130 covers and laterally encloses the gate electrode 120. That is, the ferroelectric layer 130 may be at least formed, e.g., conformally, on the upper side surface S1 and lateral side surfaces S2, S3 of the gate electrode 120 to have a substantially uniform thickness. Accordingly, the ferroelectric layer 130/131 is deposited over protruding edges and/or denting edges (defined by the side surfaces of the gate electrode 120) of the gate electrode 120, which intrinsically creates a plurality of crystalline domains (e.g., crystalline (ferroelectric) domains 132, 134, 136) without having to adjust any doping type, concentration of the ferroelectric material, and/or adjust an annealing process (e.g., changing the time and temperature of the annealing process) performed on the ferroelectric layer 130/131. The crystalline domains 132, 134, 136 (e.g., illustrate in dashed lines) distributed across the ferroelectric layer 130/131. In some embodiments, the crystalline domains (e.g., crystalline domains 132, 134, 136) may correspond to side surfaces S1, S2, S3 of the gate electrode 120. More or less crystalline domains may be formed in the ferroelectric layer 130 due to the variations in manufacturing process.

In general, a size of the crystalline domains may affect a resistance of the ferroelectric layer 130, a set voltage of the ferroelectric layer 130, a reset voltage of the ferroelectric layer 130, and/or other parameters of the ferroelectric layer 130. Thus, in some embodiments, a larger in size of the crystalline domains in each ferroelectric layer 130 across the memory array may result in a variation of resistance, set voltage, and/or reset voltage between adjacent ferroelectric memory devices in the memory array. This may reduce device performance and/or result in improper bit values in the memory array. Accordingly, in some embodiments, the ferroelectric layer 130 conformally deposited over edges of the gate electrode 120 is configured to creates multiple smaller crystalline domains in the ferroelectric layer 130. For example, during fabrication of the ferroelectric memory device 100, the ferroelectric layer 130 conformally covers the grate electrode 120, thereby covering at least two adjacent side surfaces of the gate electrode 120. By virtue of crystalline domains generated according to the topology of the surface, a plurality of crystalline domains are intrinsically created without having to adjust manufacturing process. This, in part, decreases a power consumption of the ferroelectric memory device 100, and increases endurance and reliability of the ferroelectric memory device 100. Further, reducing and/or defining the size of the crystalline domains decreases bit to bit variation in a memory array comprising an array of ferroelectric memory device 100. Accordingly, such configuration reduces the size of the ferroelectric domains in the ferroelectric layer 130, thereby decreasing power consumption of the ferroelectric memory cell, and increasing endurance and discrete data states of the ferroelectric memory cell.

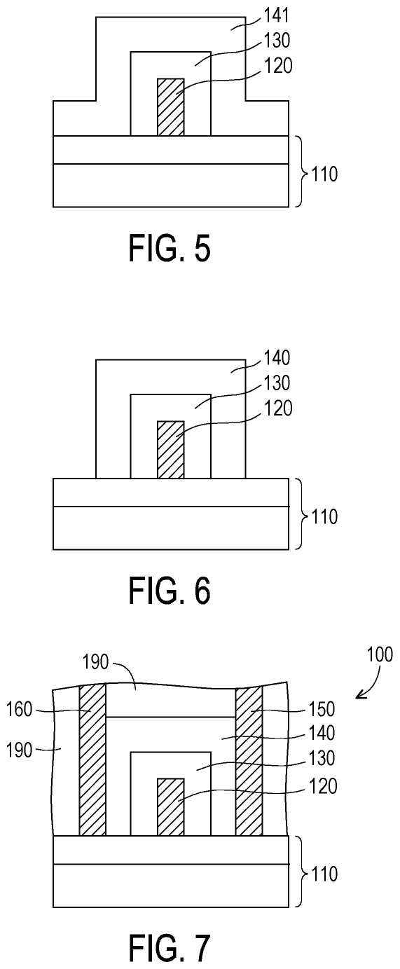

Then, referring to FIG. 5 and FIG. 6, a channel layer 140 is formed over the ferroelectric layer 130. In some embodiments, an initial channel layer 141 may be globally deposited and conformally cover the ferroelectric layers 130 and a top surface of the substrate 110, and later patterned (e.g., wet etching and/or dry etching) to form individual channel layers 140 that conformally covers the ferroelectric layers 130 respectively. In some embodiments, a thickness of the channel layer 140 is in a range of about 10 nm to about 25 nm. In some embodiments, the channel layer 140 may be formed by epitaxy growth with a semiconductor material. The semiconductor material may additionally include in-situ doping during the epitaxy growth using a precursor having semiconductor material-containing chemical and dopant-containing chemical.

Then, referring to FIG. 7, a pair of source/drain electrodes 150, 160 is formed over the substrate 110 and located on two opposite sides of the gate electrode 120 respectively. In some embodiments, the pair of source/drain electrodes 150, 160 is connected to two opposite sides of the channel layer 140. In other words, the channel layer 140 conformally covers the ferroelectric layer 130 and connects between the ferroelectric layer 130 and the pair of source/drain electrodes 150, 160. In one embodiment, the materials of the source/drain electrodes 150, 160 may be different from that of the gate electrode 120. However, in other embodiment, the materials of the source/drain electrodes 150, 160, and the gate electrode 120 may be the same.

In an embodiment, an interlayer dielectric (ILD) structure 190 may be disposed over the substrate 110 and the gate stack structure (e.g., including the gate electrode 120, the ferroelectric layer 130, etc.). The interlayer dielectric structure 190 may include one or more stacked ILD layers, which may respectively be or include, for example, an oxide (e.g., silicon dioxide), a low-k dielectric material, an extreme low-k dielectric material, another suitable dielectric material, or any combination of the foregoing. The interlayer dielectric structure 190 may be formed by, for example, chemical vapor deposition (CVD), physical vapor deposition (PVD), atomic layer deposition (ALD), or other suitable deposition or growth process. Further, the pair of source/drain electrodes 150, 160 are formed over the substrate 110 and within the interlayer dielectric structure 190. The source/drain electrodes 150, 160 may extend through the interlayer dielectric structure 190 to contact the source/drain regions in the substrate 110 respectively. In some embodiments, the source/drain electrodes 150, 160 may be formed by a single damascene process or another suitable process. In further embodiments, the source/drain electrodes 150, 160 may, for example, be or comprise aluminum, copper, tungsten, titanium nitride, tantalum nitride, another suitable conductive material, or any combination of the foregoing. It is noted that the interlayer dielectric structure 190 may be omitted in the following figures for purposes of clarity and simplicity. At this point, a ferroelectric memory device 100 with the ferroelectric layer 130 having multiple smaller crystalline domains may be substantially formed.

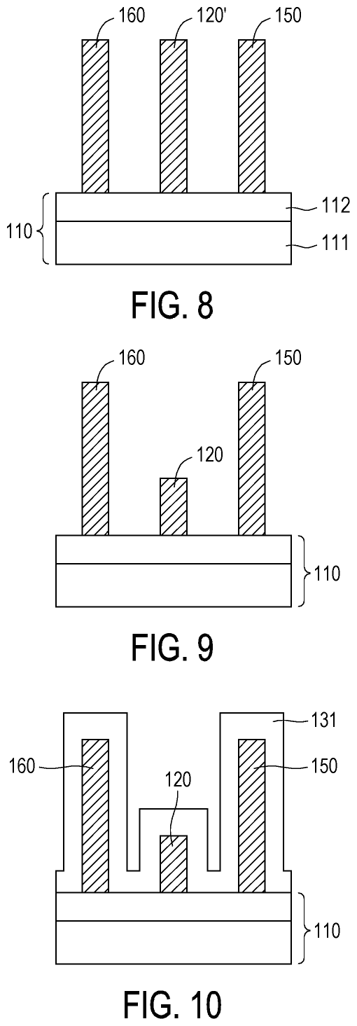

FIG. 8 to FIG. 13 illustrate partial cross sectional views of intermediate stages in the manufacturing of a ferroelectric memory device according to some embodiments of the present disclosure. It is noted that the ferroelectric memory device 100 shown in FIG. 7 may be formed by a plurality of different processes, and the disclosure merely illustrates some of the possible ones for demonstration purpose. The process shown in FIG. 8 to FIG. 13 is another one of the examples. The manufacturing process of the ferroelectric memory device shown in FIG. 8 to FIG. 13 contains many features same as or similar to the previous embodiments. For purpose of clarity and simplicity, detail description of same or similar features may be omitted, and the same or similar reference numbers denote the same or like components.

It is understood that additional operations can be provided before, during, and after the processes shown by FIG. 8 to FIG. 13, and some of the operations described below can be replaced or eliminated, for additional embodiments of the method. The order of the operations/processes may be interchangeable. Material, configuration, dimensions and/or processes the same as or similar to the foregoing embodiments described with FIG. 8 to FIG. 13 may be employed in the following embodiments, and detailed explanation thereof may be omitted.

Referring to FIG. 1 and FIG. 8, in some embodiments, the metal layer 121 shown in FIG. 1 may be firstly patterned to form a plurality of conductive contacts 120′, 150, 160 by etching (e.g., wet etching and/or dry etching) process. In one embodiment, heights of the conductive contacts 120′, 150, 160 may be substantially identical to one another since they are formed by the same etching process. The conductive contacts 150, 160 may contact the source/drain regions in the substrate 110 respectively and may function as a pair of source/drain electrodes 150, 160. The conductive contacts 120′ is deemed as a gate metal and may later be patterned to further define the shape of the gate electrode 120 as it is shown in FIG. 9.

Referring to FIG. 9, then, the gate metal 120′ may be patterned (e.g., wet etching and/or dry etching) to form the gate electrode 120. In one embodiment, the height of the gate electrode 120 may be substantially shorter than the pair of source/drain electrodes 150, 160, but the disclosure is not limited thereto. In other embodiments, any shapes and dimensions of the gate electrode 120 can be formed different from those of the source/drain electrodes 150, 160 through the second etching process. In the present embodiment, the materials of the gate electrode 120, the source/drain electrodes 150, 160 are the same.

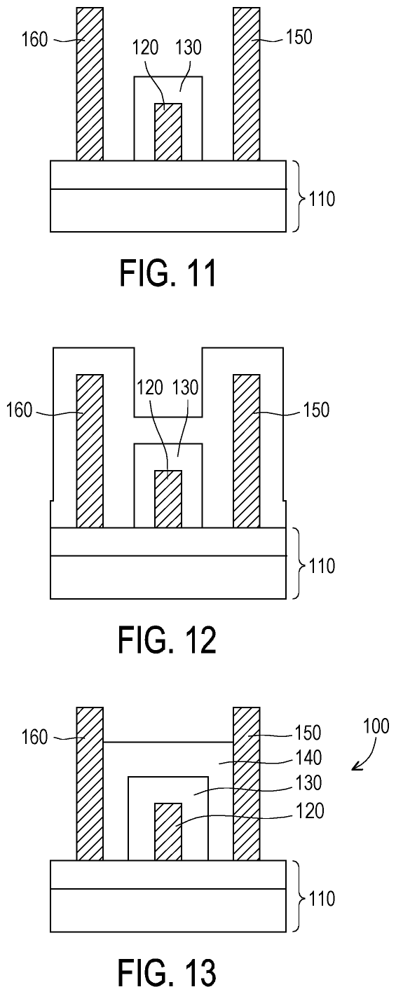

Then, referring to FIG. 10 and FIG. 11, a ferroelectric layer 130 is formed over the gate electrode 120. In some embodiment, an initial ferroelectric layer 131 may be globally deposited and conformally cover the gate electrode 120, the pair of source/drain electrodes 150, 160 and a top surface of the substrate 110, and later patterned (e.g., wet etching and/or dry etching) to form individual ferroelectric layers 130 that conformally covers the gate electrodes 120 respectively. In one embodiment, the patterned ferroelectric layers 130 exposes the pair of source/drain electrodes 150, 160, and a part of the upper surface of the substrate 110. For example, a patterning process for forming the ferroelectric layers 130 may include forming a masking layer over/on the initial ferroelectric layer 131 right above the gate electrodes 120 and patterning the initial ferroelectric layer 131 according to the masking layer by an etch (e.g., wet/wet etching and/or dry etching). The etch process removes unmasked portions of the initial ferroelectric layer 131, thereby forming the ferroelectric layers 130 conformally covering the gate electrode 120 and creating multiple crystalline domains in the ferroelectric layer 130. The material of ferroelectric layer 130 may or may not be ferroelectric prior to annealing. If it is not, it will become ferroelectric during subsequent processing. The ferroelectric layer 130 includes electric dipoles. Examples of ferroelectric materials include hafnium oxide (HfO₂), hafnium silicon oxide (HfSiO), hafnium zirconium oxide (HfZrO), aluminum oxide (Al₂O₃), titanium oxide (TiO₂), lanthanum oxide (LaOx), BaSrTiOₓ (BST), PbZrTiOₓ (PZT), or the like. Some of these materials (such as HfO₂, HfSiOₓ, HfZrOₓ, Al₂O₃, TiO₂, and LaOₓ) include the same elements as some high-k dielectric materials but may differ in the ratios of elements or in crystal structure. The ferroelectric material may be formed using CVD, PVD, ALD or the like. In some embodiments, the ferroelectric material such as HfO₂, HZO, etc., may be doped with dopants such as La, Sc, Gd, Y, Al, and C, Ge, Ni, Mo, B, etc.

Referring to FIGS. 12 and 13, then, the channel layer 140 is formed over the ferroelectric layers 130. In some embodiment, an initial channel layer 141 may be globally deposited and conformally cover the ferroelectric layers 130, the pair of source/drain electrodes 150, 160 and a top surface of the substrate 110, and later patterned (e.g., wet etching and/or dry etching) to form individual channel layers 140 that conformally covers the ferroelectric layers 130 respectively. In one embodiment, the patterned channel layer 140 covers the ferroelectric layers 130 and may fill between the ferroelectric layers 130 and the pair of source/drain electrodes 150, 160. In some embodiments, the channel layer 140 may be formed by epitaxy growth with a semiconductor material. The semiconductor material may additionally include in-situ doping during the epitaxy growth using a precursor having semiconductor material-containing chemical and dopant-containing chemical.

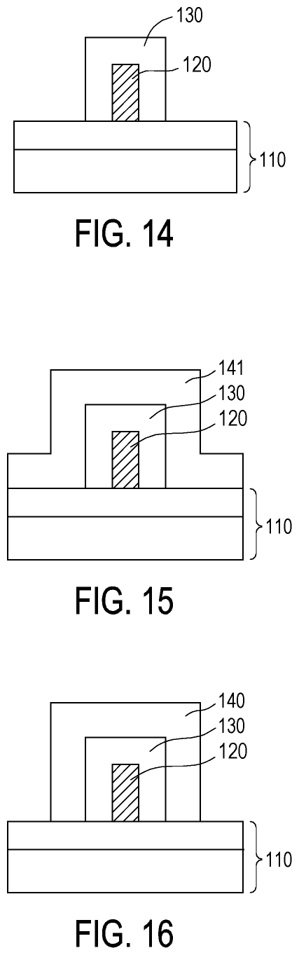

FIG. 14 to FIG. 17 illustrate another one of the possible processes for forming the ferroelectric memory device. It is noted that the manufacturing process of the ferroelectric memory device shown in FIG. 14 to FIG. 17 contains many features same as or similar to the previous embodiments. For purpose of clarity and simplicity, detail description of same or similar features may be omitted, and the same or similar reference numbers denote the same or like components. It is understood that additional operations can be provided before, during, and after the processes shown by FIG. 8 to FIG. 13, and some of the operations described below can be replaced or eliminated, for additional embodiments of the method. The order of the operations/processes may be interchangeable. Material, configuration, dimensions and/or processes the same as or similar to the foregoing embodiments described with FIG. 14 to FIG. 17 may be employed in the following embodiments, and detailed explanation thereof may be omitted.

Referring to FIG. 14, in some embodiments, the gate electrode 120 may be firstly formed by the process (e.g., single etching process or multiple phases of etching process) described above. Then, the ferroelectric layer 130 may be selectively deposited on the gate electrode 120, thereby forming the ferroelectric layers 130 conformally covering the gate electrode 120 and creating multiple crystalline domains in the ferroelectric layer 130. In some embodiments, the ferroelectric layer 130 may be selectively deposited using CVD, PVD, ALD, or a similar selective process.

With now reference to FIG. 15 and FIG. 16, in some embodiments, a channel layer 140 is formed over the ferroelectric layer 130. In some embodiments, an initial channel layer 141 may be globally deposited and conformally cover the ferroelectric layers 130 and a top surface of the substrate 110, and later patterned (e.g., wet etching and/or dry etching) to form individual channel layers 140 that conformally covers the ferroelectric layers 130 respectively. In some embodiments, a thickness of the channel layer 140 is in a range of about 10 nm to about 25 nm. In some embodiments, the channel layer 140 may be formed by epitaxy growth with a semiconductor material. The semiconductor material may additionally include in-situ doping during the epitaxy growth using a precursor having semiconductor material-containing chemical and dopant-containing chemical.

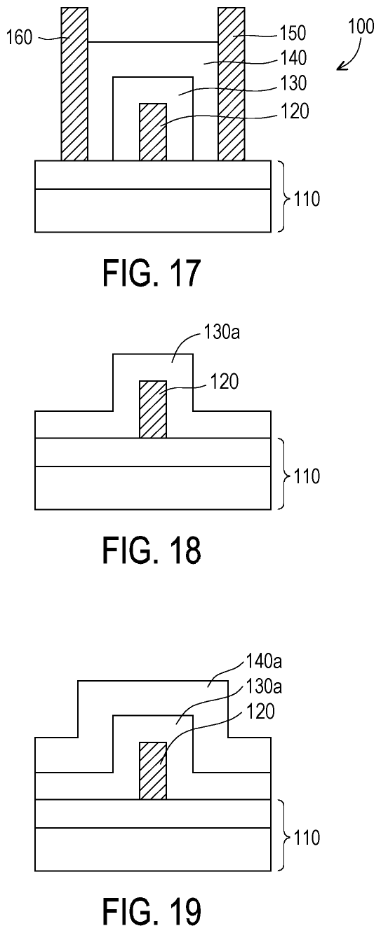

With now reference to FIG. 17, in some embodiments, a pair of source/drain electrodes 150, 160 is formed over the substrate 110 and located on two opposite sides of the gate electrode 120 respectively. In some embodiments, the pair of source/drain electrodes 150, 160 is connected to two opposite sides of the channel layer 140. In other words, the channel layer 140 conformally covers the ferroelectric layer 130 and connects between the ferroelectric layer 130 and the pair of source/drain electrodes 150, 160. In some embodiments, the source/drain electrodes 150, 160 may be formed by a single damascene process or another suitable process. In further embodiments, the source/drain electrodes 150, 160 may, for example, be or comprise aluminum, copper, tungsten, titanium nitride, tantalum nitride, another suitable conductive material, or any combination of the foregoing. In one embodiment, the materials of the source/drain electrodes 150, 160 may be different from that of the gate electrode 120. However, in other embodiment, the materials of the source/drain electrodes 150, 160, and the gate electrode 120 may be the same.

FIG. 18 to FIG. 20 illustrate partial cross sectional views of intermediate stages in the manufacturing of a ferroelectric memory device according to some embodiments of the present disclosure. It is noted that the ferroelectric memory device and the manufacturing process thereof shown in FIG. 18 to FIG. 20 contains many features same as or similar to the previous embodiments. For purpose of clarity and simplicity, detail description of same or similar features may be omitted, and the same or similar reference numbers denote the same or like components. It is understood that additional operations can be provided before, during, and after the processes shown by FIG. 18 to FIG. 20, and some of the operations described below can be replaced or eliminated, for additional embodiments of the method. The order of the operations/processes may be interchangeable. Material, configuration, dimensions and/or processes the same as or similar to the foregoing embodiments described with FIG. 18 to FIG. 20 may be employed in the following embodiments, and detailed explanation thereof may be omitted.

Referring to FIG. 18, in accordance with some embodiments of the disclosure, the gate electrode 120 may be firstly formed by the process (e.g., single etching process or multiple phases of etching process) described above. Then, a ferroelectric layer 130a is formed over the gate electrode 120. In some embodiment, the ferroelectric layer 130a conformally cover the gate electrode 120 and at least a part of the top surface of the substrate 110. In one embodiment, the ferroelectric layer 130a may be at least extended over the source/drain regions in the substrate 110. In some embodiments, a thickness of the ferroelectric layer 130a may be controlled or tuned based on the device design or circuit design of the ferroelectric memory device. In some embodiments, the thickness of ferroelectric layer 130a is in the range from 1 nm to 15 nm. The material of ferroelectric layer 130a may or may not be ferroelectric prior to annealing. If it is not, it will become ferroelectric during subsequent processing. The ferroelectric layer 130a includes electric dipoles. Examples of ferroelectric materials include hafnium oxide (HfO₂), hafnium silicon oxide (HfSiO), hafnium zirconium oxide (HfZrO), aluminum oxide (Al₂O₃), titanium oxide (TiO₂), lanthanum oxide (LaOx), BaSrTiOₓ (BST), PbZrTiOₓ (PZT), or the like. Some of these materials (such as HfO₂, HfSiOₓ, HfZrOₓ, Al₂O₃, TiO₂, and LaOₓ) include the same elements as some high-k dielectric materials but may differ in the ratios of elements or in crystal structure. The ferroelectric material may be formed using CVD, PVD, ALD or the like.

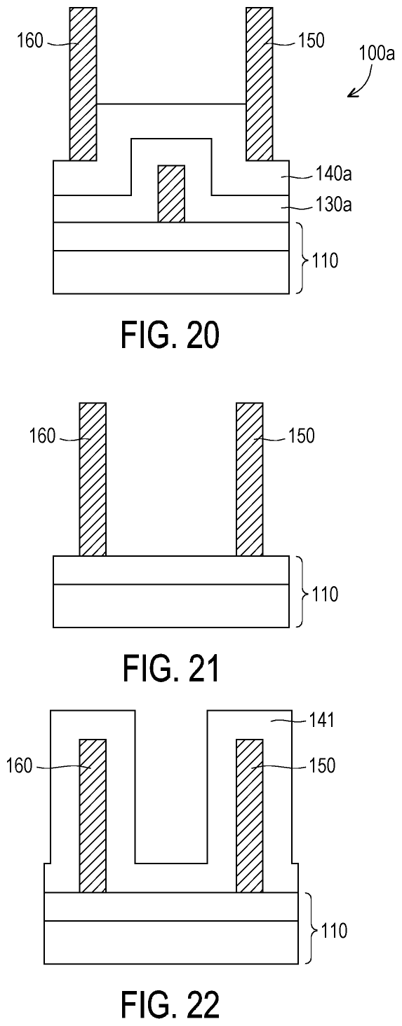

Then, referring to FIG. 20, in some embodiments, a channel layer 140a is formed over the ferroelectric layer 130a. In some embodiments, the channel layer 140a conformally covers the ferroelectric layers 130a and is also extended over the source/drain regions in the substrate 110. In some embodiments, a thickness of the channel layer 140a is in a range of about 10 nm to about 25 nm. In some embodiments, the channel layer 140a may be formed by epitaxy growth with a semiconductor material. The semiconductor material may additionally include in-situ doping during the epitaxy growth using a precursor having semiconductor material-containing chemical and dopant-containing chemical.

Then, referring to FIG. 20, a pair of source/drain electrodes 150, 160 is formed over the channel layer 140a and over the source/drain regions in the substrate 110. Accordingly, the ferroelectric layer 130a and the channel 140a are overlapped with the pair of source/drain electrodes 150, 160 from a top view. In one embodiment, the materials of the source/drain electrodes 150, 160 may be different from that of the gate electrode 120. However, in other embodiment, the materials of the source/drain electrodes 150, 160, and the gate electrode 120 may be the same. In some embodiments, the source/drain electrodes 150, 160 may be formed by a single damascene process or another suitable process. In further embodiments, the source/drain electrodes 150, 160 may, for example, be or comprise aluminum, copper, tungsten, titanium nitride, tantalum nitride, another suitable conductive material, or any combination of the foregoing.

FIG. 21 to FIG. 26 illustrate partial cross sectional views of intermediate stages in the manufacturing of a ferroelectric memory device according to some embodiments of the present disclosure. It is noted that the ferroelectric memory device and the manufacturing process thereof shown in FIG. 21 to FIG. 26 contains many features same as or similar to the previous embodiments. For purpose of clarity and simplicity, detail description of same or similar features may be omitted, and the same or similar reference numbers denote the same or like components. It is understood that additional operations can be provided before, during, and after the processes shown by FIG. 21 to FIG. 26, and some of the operations described below can be replaced or eliminated, for additional embodiments of the method. The order of the operations/processes may be interchangeable. Material, configuration, dimensions and/or processes the same as or similar to the foregoing embodiments described with FIG. 21 to FIG. 26 may be employed in the following embodiments, and detailed explanation thereof may be omitted.

Referring to FIG. 1 and FIG. 21, in accordance with some embodiments of the disclosure, a pair of source/drain electrodes 150, 160 may be firstly formed over the substrate 110 by patterning the metal layer 121 shown in FIG. 1 through etching (e.g., wet etching and/or dry etching) process. In some embodiments, the source/drain electrodes 150, 160 may, for example, be or comprise aluminum, copper, tungsten, titanium nitride, tantalum nitride, another suitable conductive material, or any combination of the foregoing.

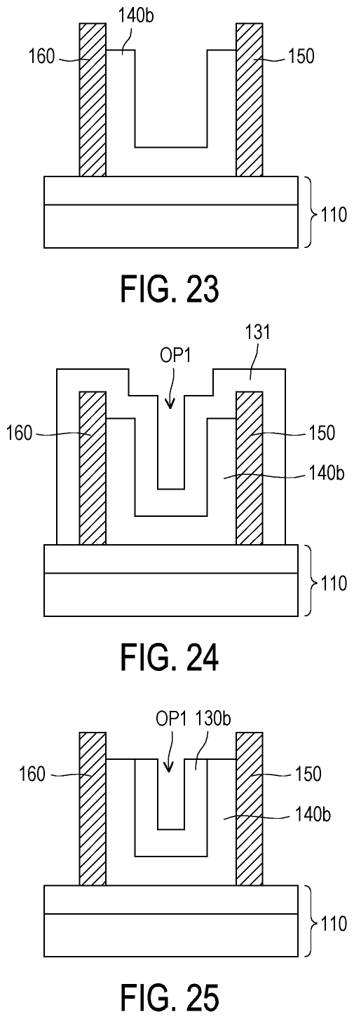

Then, referring to FIG. 22 and FIG. 23, a channel layer 140b is formed to conformally cover a region between the pair of source/drain electrodes 150, 160. In some embodiments, an initial channel layer 141 may be globally deposited and conformally cover the pair of source/drain electrodes 150, 160 and a top surface of the substrate 110, and later patterned (e.g., wet etching and/or dry etching) to form the channel layer 140b that conformally covers the region between the pair of source/drain electrodes 150, 160. In one embodiment, the channel layer 140b conformally covers corresponding surfaces of the source/drain electrodes 150, 160 that face each other and a top surface of the substrate that is between the source/drain electrodes 150, 160. The channel layer 140b may be patterned by a single etching process or multiple etching processes to arrive the resultant structure shown in FIG. 23. In the present embodiment, the channel layer 140b exposes a top portion the source/drain electrodes 150, 160. However, in other embodiment, the channel layer 140b may comprehensively cover the corresponding surfaces of the source/drain electrodes 150, 160 that face each other. In some embodiments, a thickness of the channel layer 140b is in a range of about 10 nm to about 25 nm. In some embodiments, the channel layer 140b may be formed by epitaxy growth with a semiconductor material. The semiconductor material may additionally include in-situ doping during the epitaxy growth using a precursor having semiconductor material-containing chemical and dopant-containing chemical.

Then, referring to FIG. 24 and FIG. 25, a ferroelectric layer 130b is formed to conformally cover the channel layer 140b. In some embodiments, an initial ferroelectric layer 130b may be globally deposited and conformally cover the channel layer 140b, and a part of the source/drain electrodes 150, 160 that is exposed by the channel layer 140b, and later patterned (e.g., wet etching and/or dry etching) to form the ferroelectric layer 130b that conformally covers the channel layer 140b. In some embodiments, an upper surface of the channel layer 140b defines a concave as shown in FIG. 23, and the ferroelectric layer 130b conformally covers the sidewall of the concave defined by the channel layer 140b. The ferroelectric layer 130b may be patterned by a single etching process or multiple etching processes to arrive the resultant structure shown in FIG. 25. In some embodiments, the ferroelectric layer 130b is patterned to expose the source/drain electrodes 150, 160, and a top surface of the ferroelectric layer 130b is substantially coplanar with a top surface of the channel layer 140b. In some embodiments, the ferroelectric layer 130b is deposited over the concave defined by the channel layer 140b. That is, the surface where the ferroelectric layer 130b is deposited includes dented edges, which intrinsically creates a plurality of crystalline domains (e.g., crystalline domains 132, 134, 136) in the ferroelectric layer 130b without having to adjust any doping type, concentration of the ferroelectric material, and/or adjust an annealing process (e.g., changing the time and temperature of the annealing process) performed on the ferroelectric layer 130b. Accordingly, such configuration reduces the size of the ferroelectric domains in the ferroelectric layer 130b, thereby decreasing power consumption of the ferroelectric memory cell, and increasing endurance and discrete data states of the ferroelectric memory cell.

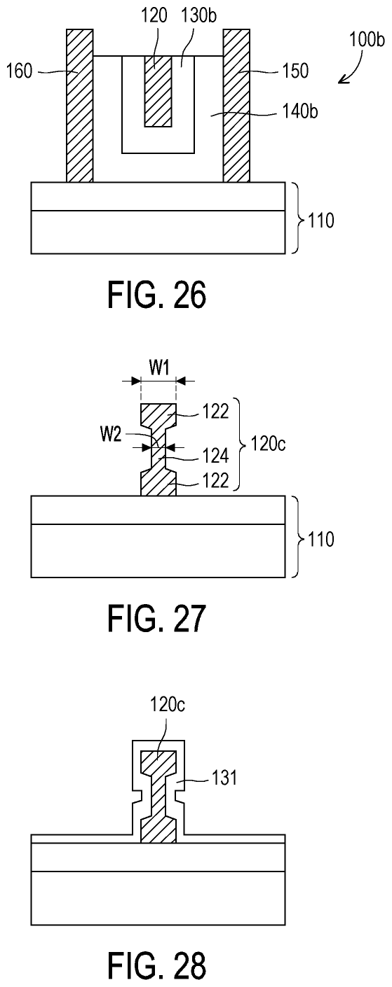

Then, referring to FIG. 25 and FIG. 26, a gate electrode 120 is formed over the ferroelectric layer 130b. In some embodiments, an upper surface of the ferroelectric layer 130b defines a concave OP1 as it is shown in FIG. 25, and the gate electrode 120 fills the concave OP1. In some embodiments, a top surface of the channel layer 140b, a top surface of the ferroelectric layer 130b and a top surface of the gate electrode 120 are substantially coplanar with one another. In the present embodiment, the ferroelectric layer 130b is disposed between the substrate 110 and the gate electrode 120, and the ferroelectric layer 130b conformally covers a bottom side surface and lateral side surfaces of the gate electrode 120. In structural point of view, the ferroelectric layer 130b rises to the height of the gate electrode 120 to encapsulate the gate electrode 120, and the crystalline domains in the ferroelectric layer 130b may correspond to side surfaces of the gate electrode 120 and the side surfaces of the concave OP1 defined by the channel layer 140b. However, more or less crystalline domains may be formed in the ferroelectric layer 130b due to the variations in manufacturing process.

FIG. 27 to FIG. 32 illustrate partial cross sectional views of intermediate stages in the manufacturing of a ferroelectric memory device according to some embodiments of the present disclosure. It is noted that the ferroelectric memory device and the manufacturing process thereof shown in FIG. 27 to FIG. 32 contains many features same as or similar to the previous embodiments. For purpose of clarity and simplicity, detail description of same or similar features may be omitted, and the same or similar reference numbers denote the same or like components. It is understood that additional operations can be provided before, during, and after the processes shown by FIG. 27 to FIG. 32, and some of the operations described below can be replaced or eliminated, for additional embodiments of the method. The order of the operations/processes may be interchangeable. Material, configuration, dimensions and/or processes the same as or similar to the foregoing embodiments described with FIG. 27 to FIG. 32 may be employed in the following embodiments, and detailed explanation thereof may be omitted.

With now reference to FIG. 27, in some embodiments, a gate electrode 120a including at least one head portion 122 and at least one neck portion 124 is formed over the substrate 110. In some embodiments, the head portion 122 is adjacent to the neck portion 124, and a width W2 of the neck portion 124 is smaller than a width W1 of the head portion 124. In other words, the head portion 122 is adjacent to and wider than the neck portion 124. In the present embodiment, the gate electrode 120a has concave sidewalls which form a tapered or hourglass shape, which includes two head portions 122 and a neck portion 124 connected between the two head portions 122. However, the disclosure is not limited thereto. Any shapes with variations in widths, lengths, thicknesses may be applied herein. In other words, the gate electrode may include more or less head portions 122 and/or more than one neck portions 124. One of the possible processes of forming such gate electrode may be described later on.

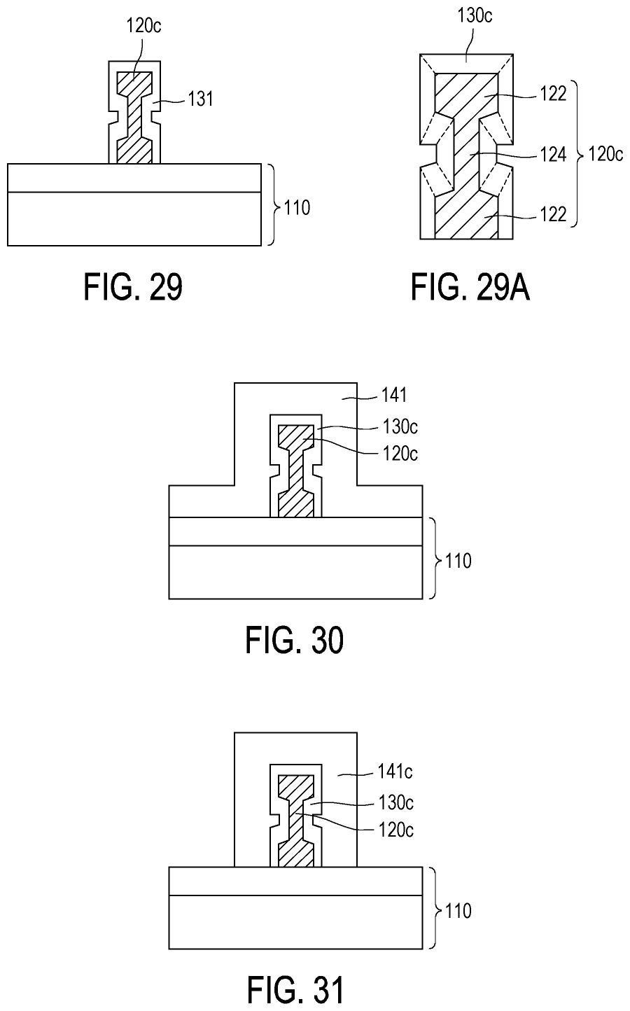

With now reference to FIG. 28 and FIG. 29, in some embodiments, a ferroelectric layer 130c is formed over the gate electrode 120. In some embodiment, an initial ferroelectric layer 131 may be globally deposited and conformally cover the gate electrode 120a and a top surface of the substrate 110, and later patterned (e.g., wet etching and/or dry etching) to form individual ferroelectric layers 130c that conformally covers the gate electrodes 120a respectively. In some embodiments, the thickness of ferroelectric layer 130c is in the range from 1 nm to 15 nm. The material of the ferroelectric layer 130c may or may not be ferroelectric prior to annealing. If it is not, it will become ferroelectric during subsequent processing. The ferroelectric layer 130 includes electric dipoles. Examples of ferroelectric materials include hafnium oxide (HfO₂), hafnium silicon oxide (HfSiO), hafnium zirconium oxide (HfZrO), aluminum oxide (Al₂O₃), titanium oxide (TiO₂), lanthanum oxide (LaOx), BaSrTiOₓ (BST), PbZrTiOₓ (PZT), or the like. Some of these materials (such as HfO₂, HfSiOₓ, HfZrOₓ, Al₂O₃, TiO₂, and LaOₓ) include the same elements as some high-k dielectric materials but may differ in the ratios of elements or in crystal structure. The ferroelectric material may be formed using CVD, PVD, ALD or the like. In an alternative embodiment, the ferroelectric layer 130c may further extend over the source/drain regions in the substrate 110 as it is shown in the embodiment of FIG. 18.

Referring to FIG. 29 and FIG. 29A, in accordance with some embodiments of the disclosure, the ferroelectric layer 130c conformally covers the neck portion 124 and the head portions 122 of the gate electrode 120a. That is, the ferroelectric layer 13c0 may be at least formed, e.g., conformally, on the neck portion 124 and the head portions 122 of the gate electrode 120a to have a substantially uniform thickness. Accordingly, the ferroelectric layer 130c is deposited over protruding edges and denting edges (defined by surfaces of the neck portion 124 and the head portions 122) of the gate electrode 120a, which intrinsically creates a plurality of crystalline domains (e.g., crystalline domains that are illustrated by dash lines in FIG. 29A) without having to adjust any doping type, concentration of the ferroelectric material, and/or adjust an annealing process (e.g., changing the time and temperature of the annealing process) performed on the ferroelectric layer 130c. The crystalline domains distributed across the ferroelectric layer 130c, and may correspond to side surfaces of the neck portion 124 and the head portions 122. It is noted that the crystalline domains illustrated by dash lines in FIG. 29A are merely for illustration purpose. More or less crystalline domains may be formed in the ferroelectric layer 130c due to the variations in manufacturing process.

Referring to FIG. 30 and FIG. 31, a channel layer 140c is formed over the ferroelectric layer 130c. In some embodiments, an initial channel layer 141 may be globally deposited and conformally cover the ferroelectric layers 130 and a top surface of the substrate 110, and later patterned (e.g., wet etching and/or dry etching) to form individual channel layers 140c that conformally covers the ferroelectric layers 130c respectively. In some embodiments, a thickness of the channel layer 140c is in a range of about 10 nm to about 25 nm. In some embodiments, the channel layer 140c may be formed by epitaxy growth with a semiconductor material. The semiconductor material may additionally include in-situ doping during the epitaxy growth using a precursor having semiconductor material-containing chemical and dopant-containing chemical. In the embodiment of the ferroelectric layer 130c further extending over the source/drain regions in the substrate 110, the channel layer 140c may also extend over the source/drain regions in the substrate 110 as it is shown in the embodiment of FIG. 19.

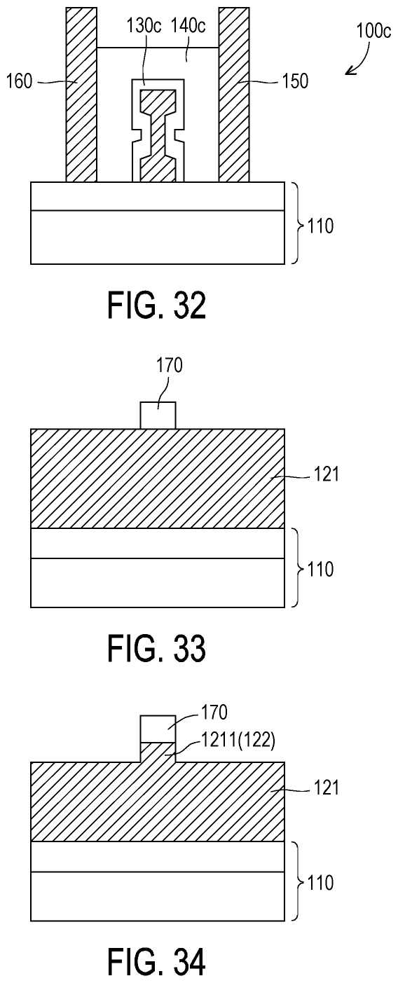

Then, referring to FIG. 32, a pair of source/drain electrodes 150, 160 is formed over the substrate 110 and located on two opposite sides of the gate electrode 120a respectively. In some embodiments, the pair of source/drain electrodes 150, 160 is connected to two opposite sides of the channel layer 140c. In other words, the channel layer 140c conformally covers the ferroelectric layer 130c and connects between the ferroelectric layer 130c and the pair of source/drain electrodes 150, 160. In one embodiment, the materials of the source/drain electrodes 150, 160 may be different from that of the gate electrode 120a. However, in other embodiment, the materials of the source/drain electrodes 150, 160, and the gate electrode 120a may be the same. In some embodiments, the source/drain electrodes 150, 160 may be formed by a single damascene process or another suitable process. In further embodiments, the source/drain electrodes 150, 160 may, for example, be or comprise aluminum, copper, tungsten, titanium nitride, tantalum nitride, another suitable conductive material, or any combination of the foregoing. In the embodiment of the ferroelectric layer 130c and the channel layer 140c further extending over the source/drain regions in the substrate 110, the pair of source/drain electrodes 150, 160 may be formed on the channel layer 140c and overlap with the source/drain regions in the substrate 110 from a top view, as it is shown in the embodiment of FIG. 20.

FIG. 33 to FIG. 37 illustrate partial cross sectional views of intermediate stages in the manufacturing of a ferroelectric memory device according to some embodiments of the present disclosure. It is noted that the gate electrode 120a shown in FIG. 27 may be formed by a plurality of different processes, and FIG. 33 to FIG. 37 merely illustrate one of the possible ones for demonstration purpose. It is understood that additional operations can be provided before, during, and after the processes shown by FIG. 33 to FIG. 37, and some of the operations described below can be replaced or eliminated, for additional embodiments of the method. The order of the operations/processes may be interchangeable. Material, configuration, dimensions and/or processes the same as or similar to the foregoing embodiments described with FIG. 33 to FIG. 37 may be employed in the following embodiments, and detailed explanation thereof may be omitted.

Referring to FIG. 33 and FIG. 34, a mask layer (e.g., photoresist layer) 170 may be provided over the metal layer 121 on the substrate 110 and covers a region where the gate electrode 120a is to be formed. In an embodiment, the metal layer 121 may be patterned by a first etching (e.g., wet and/or dry etching) process, such as an anisotropic etching process. An upper portion 1211 (e.g., the head portion 122) of the gate electrode 120 may be formed, and is protruded from the patterned upper surface of the metal layer 121′.

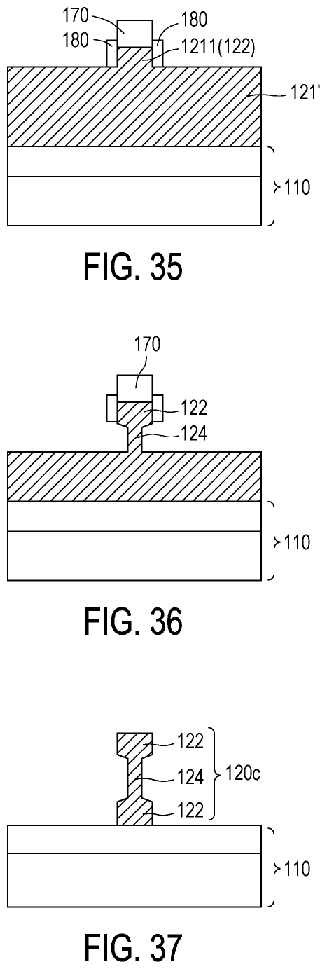

Referring to FIG. 35 and FIG. 36, in some embodiments, a passivation layer 180 is deposited, for example, in-situ (without interrupting the process) to protect the upper portion 1211 (e.g., the head portion 122) from etching laterally during the subsequent patterning process. Then, a second etching process may be performed over the metal layer 121′. During the second etching process, the passivation layer 180 may function as an etch control layer, which may have a different etch rate than the metal layer 121′. Accordingly, the etchant of the etching process will etch the passivation layer 180 at a lower rate than the metal layer 121′. As a result of the etch process, the sidewalls of the upper portion 1211 covered by the passivation layer 180 may be substantially perpendicular to the top surface of the substrate 110. The passivation layer 180 may be substantially unaffected by the etching process and may allow the etch process to undercut the metal layer 121′. In an embodiment, the second etching process may be an isotropic etching process, or the like. The second etching process further etches the metal layer 121′ underneath to form the neck portion 124 in, for example, a tapered or an hourglass shape. The sidewalls of the neck portion 124 may not be parallel or perpendicular to the top surface of the substrate 110.

In accordance with some embodiments of the disclosure, by modulating multiple phases of etching processes and passivation layers, an hourglass (or dumbbell) shape of the gate electrode 120a as shown in FIG. 37, which has the neck region 124 and the head portions 122 adjacent to and wider than the neck portion 124, can be achieved. However, the disclosure is not limited thereto. Any shapes of the gate electrode with variations in widths, lengths, thicknesses can be formed by modulating multiple phases of etching processes and passivation layers.

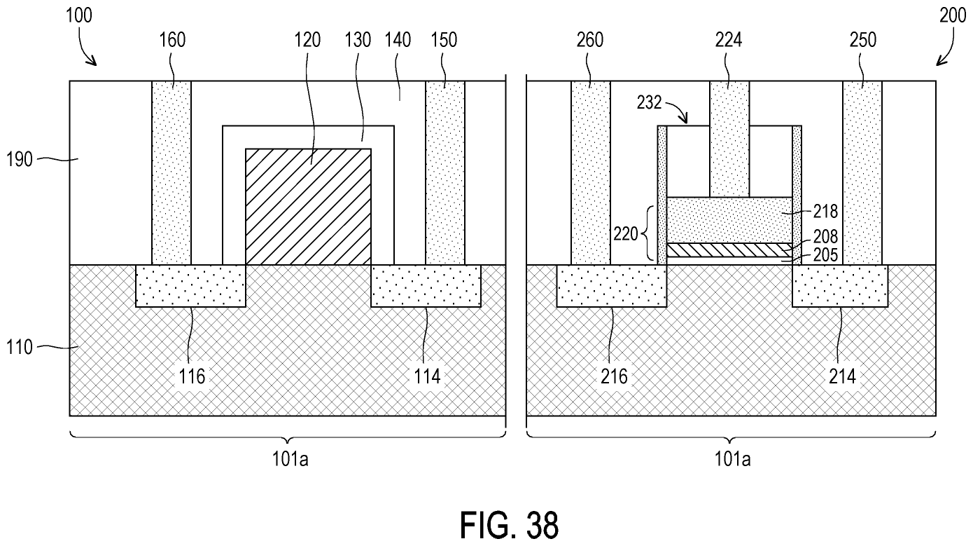

FIG. 38 illustrates a cross-sectional view of some embodiments of an integrated chip comprising a logic device and a ferroelectric memory device. In accordance with some embodiments of the disclosure, as shown in FIG. 38, an integrated chip 10 includes any one of the ferroelectric memory devices illustrated above and a logic device 200 may be provided. It is noted that the ferroelectric memory device 100 shown in FIG. 7 is illustrate herein, but it should be understood that other ferroelectric memory devices illustrated in the disclosure may also be applied to the integrated chip 10. Regarding the ferroelectric memory device 100, material, configuration, dimensions and/or processes the same as or similar to the foregoing embodiments may be employed in the following embodiments, and detailed explanation thereof may be omitted.

In some embodiments, the integrated chip 10 includes the substrate 110, the ferroelectric memory device 100, and the logic device 200. The substrate 110 includes a memory region 101a and a logic region 101b. The ferroelectric memory device 100 is disposed in the memory region 101a and the logic device 200 is disposed in the logic region 101b. In one embodiment, the logic device 200 includes a logic device gate stack 220 disposed over the substrate 110. In some embodiments, the logic device gate stack 220 may include, for example, an interfacial dielectric layer 205, the gate dielectric 208, and the gate electrode 218, disposed in that order from bottom to top. However, the logic device gate stack 220 may have different compositions in other embodiments. In some embodiments, a plurality of conductive contacts 224 may extend to reach on the gate electrode 218 for the logic device 200. A metal gate cutting dielectric 232 may separate the gate electrode 120 of the ferroelectric memory device 100 and the logic device 200. The metal gate cutting dielectric 232 may include silicon dioxide or other dielectric materials.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a ferroelectric memory device includes a substrate, a gate electrode, a ferroelectric layer, and a pair of source/drain electrodes. The gate electrode is disposed over the substrate. The ferroelectric layer at least covers two adjacent side surfaces of the gate electrode. The pair of source/drain electrodes is over the substrate and disposed on two opposite sides of the gate electrode respectively. In an embodiment, the ferroelectric layer covers and laterally encloses the gate electrode. In an embodiment, the ferroelectric memory device further includes a channel layer covering the ferroelectric layer and between the ferroelectric layer and the pair of source/drain electrodes. In an embodiment, the ferroelectric layer conformally covers the gate electrode and an upper surface of the substrate. In an embodiment, the ferroelectric memory device further includes a channel layer conformally covering the ferroelectric layer. In an embodiment, the pair of source/drain electrodes are disposed on the channel layer. In an embodiment, the ferroelectric memory device further includes a channel layer conformally covering a region between the pair of source/drain electrodes. In an embodiment, the ferroelectric layer conformally covers the channel layer and an upper surface of the ferroelectric layer defines a concave. In an embodiment, the gate electrode fills the concave, and a top surface of the channel layer, a top surface of the ferroelectric layer and a top surface of the gate electrode are substantially coplanar with one another. In an embodiment, the gate electrode includes a neck portion and a head portion adjacent to the neck portion, and a width of the neck portion is smaller than a width of the head portion. In an embodiment, the ferroelectric layer conformally covers the neck portion and the head portion.

In accordance with some embodiments of the disclosure, an integrated chip includes a substrate, a logic device, and a ferroelectric memory device. The substrate includes a logic region and a memory region. The logic device is disposed in the logic region. The ferroelectric memory device is disposed in the memory region and includes a gate electrode, and a ferroelectric layer conformally covering the gate electrode and including a plurality of crystalline domains corresponding to side surfaces of the gate electrode. In an embodiment, the ferroelectric memory device further includes a pair of source/drain electrodes disposed on two opposite sides of the gate electrode respectively. In an embodiment, the ferroelectric layer is overlapped with the pair of source/drain electrodes from a top view. In an embodiment, the ferroelectric layer is disposed between the substrate and the gate electrode, and a top surface of the ferroelectric layer is substantially coplanar with a top surface of the gate electrode. In an embodiment, the gate electrode includes a neck portion and a head portion adjacent to and wider than the neck portion, and the ferroelectric layer conformally covers the neck portion and the head portion.

In accordance with some embodiments of the disclosure, a manufacturing method of a ferroelectric memory device includes forming a gate electrode over a substrate; forming a ferroelectric layer conformally covering the gate electrode; forming a channel layer conformally covering the ferroelectric layer; and forming a pair of source/drain electrodes over the substrate. In an embodiment, the ferroelectric layer conformally covering the gate electrode and an upper surface of the substrate, and the pair of source/drain electrodes are formed over the channel layer. In an embodiment, the manufacturing method of the ferroelectric memory device further includes: patterning a metal layer over the substrate to form a gate metal and the pair of source/drain electrodes; and patterning the gate metal to form the gate electrode. In an embodiment, the gate electrode is formed by a plurality of etching processes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A ferroelectric memory device, comprising:
a substrate;
a gate electrode disposed over the substrate;
a ferroelectric layer at least covering two adjacent side surfaces of the gate electrode;
a pair of source/drain electrodes over the substrate and disposed on two opposite sides of the gate electrode respectively.

2. The ferroelectric memory device as claimed in claim 1, wherein the ferroelectric layer covers and laterally encloses the gate electrode.

3. The ferroelectric memory device as claimed in claim 1, further comprising a channel layer covering the ferroelectric layer and between the ferroelectric layer and the pair of source/drain electrodes.

4. The ferroelectric memory device as claimed in claim 1, wherein the ferroelectric layer conformally covers the gate electrode and an upper surface of the substrate.

5. The ferroelectric memory device as claimed in claim 4, further comprising a channel layer conformally covering the ferroelectric layer.

6. The ferroelectric memory device as claimed in claim 4, wherein the pair of source/drain electrodes are disposed on the channel layer.

7. The ferroelectric memory device as claimed in claim 1, further comprising a channel layer conformally covering a region between the pair of source/drain electrodes.

8. The ferroelectric memory device as claimed in claim 7, wherein the ferroelectric layer conformally covers the channel layer and an upper surface of the ferroelectric layer defines a concave.

9. The ferroelectric memory device as claimed in claim 8, wherein the gate electrode fills the concave, and a top surface of the channel layer, a top surface of the ferroelectric layer and a top surface of the gate electrode are substantially coplanar with one another.

10. The ferroelectric memory device as claimed in claim 1, wherein the gate electrode comprises a neck portion and a head portion adjacent to the neck portion, and a width of the neck portion is smaller than a width of the head portion.

11. The ferroelectric memory device as claimed in claim 10, wherein the ferroelectric layer conformally covers the neck portion and the head portion.

12. An integrated chip, comprising:
a substrate comprises a logic region and a memory region;
a logic device disposed in the logic region; and
a ferroelectric memory device disposed in the memory region and comprising a gate electrode, and a ferroelectric layer conformally covering the gate electrode and comprising a plurality of crystalline domains corresponding to side surfaces of the gate electrode.

13. The integrated chip as claimed in claim 12, wherein the ferroelectric memory device further comprising a pair of source/drain electrodes disposed on two opposite sides of the gate electrode respectively.

14. The integrated chip as claimed in claim 13, wherein the ferroelectric layer is overlapped with the pair of source/drain electrodes from a top view.

15. The integrated chip as claimed in claim 12, wherein the ferroelectric layer is disposed between the substrate and the gate electrode, and a top surface of the ferroelectric layer is substantially coplanar with a top surface of the gate electrode.

16. The integrated chip as claimed in claim 12, wherein the gate electrode comprises a neck portion and a head portion adjacent to and wider than the neck portion, and the ferroelectric layer conformally covers the neck portion and the head portion.

17. A manufacturing method of a ferroelectric memory device, comprising:
forming a gate electrode over a substrate;
forming a ferroelectric layer conformally covering the gate electrode;
forming a channel layer conformally covering the ferroelectric layer; and
forming a pair of source/drain electrodes over the substrate.

18. The manufacturing method of the ferroelectric memory device as claimed in claim 17, wherein the ferroelectric layer conformally covering the gate electrode and an upper surface of the substrate, and the pair of source/drain electrodes are formed over the channel layer.

19. The manufacturing method of the ferroelectric memory device as claimed in claim 17, further comprising:
patterning a metal layer over the substrate to form a gate metal and the pair of source/drain electrodes; and
patterning the gate metal to form the gate electrode.

20. The manufacturing method of the ferroelectric memory device as claimed in claim 17, wherein the gate electrode is formed by a plurality of etching processes.
